(19) United States
(12) Patent Application Publication
(10) Pub. No.: US 2025/0294800 A1
(43) Pub. Date: Sep. 18, 2025

(54) TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); George Dorman, Chandler, AZ (US); Bruce Odekirk, Portland, OR (US); Randy L. Yach, Phoenix, AZ (US)

(73) Assignee: Microchip Technology Incorporated, Chandler, AZ (US)

(21) Appl. No.: 18/828,739

(22) Filed: Sep. 9, 2024

Related U.S. Application Data
(60) Provisional application No. 63/566,464, filed on Mar. 18, 2024.

(51) Int. Cl. H01L 29/78; H01L 29/08; H01L 29/51; H01L 29/66

(52) U.S. Cl. CPC H10D 30/66; H10D 30/0291; H10D 30/0516; H10D 62/153; H10D 64/68

(57) ABSTRACT

A transistor that may include a substrate. A drift layer on the substrate. The drift layer having a recessed portion and a protruding portion. A well layer within the recessed portion of the drift layer and sides of the protruding portion of the drift layer. A source layer within a portion of the recessed portion of the drift layer and the protruding portion of the drift layer. A JFET layer within the protruding portion of the drift layer. An insulating layer over a portion of the source layer and over a portion of the well layer on the sides of the protruding portion of the drift layer. A gate electrode over a portion of the insulating layer.

### CROSS-REFERENCE TO RELATED APPLICATION

The present application claims priority to U.S. Provisional Patent Application No. 63/566,464, filed on Mar. 18, 2024, the contents of which are hereby incorporated by reference in their entirety.

### TECHNICAL FIELD

The present disclosure relates to semiconductor devices, and more specifically to transistors and methods for manufacturing same to increase the performance for a low capacitance transistor.

### SUMMARY

This invention is about a highly rugged, high performance, and low capacitance power transistor.

According to an aspect of one or more examples, there is provided a method for manufacturing a transistor that may include providing a substrate, forming a drift layer on the substrate having a protruding portion, implanting a well layer into the drift layer and into sides of the protruding portion of the drift layer, forming a recess portion into the well layer, implanting a source layer into a portion of the recessed portion of the well layer and extending into an undercut in the well layer and into well layer along the sides of the protruding portion of the drift layer, implanting a JFET layer into the protruding portion in the drift layer, forming an insulating layer over a portion of the source layer and over a portion of the well layer on the sides of the protruding portion of the drift layer, and forming a gate electrode over the insulating layer. The substrate may comprise a first concentration of a first type dopant. The drift layer may comprise a second concentration of the first type dopant, the first concentration may be greater than the second concentration. The well layer may comprise a third concentration of a second type dopant. The source layer may comprise a fourth concentration of the first type dopant. The JFET layer may comprise a fifth concentration of the first type dopant. The insulating layer may comprise polysilicon, oxide or a mixture of polysilicon and oxide. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided a transistor that may include a substrate, a drift layer on the substrate, the drift layer having a protruding portion, a well layer within the drift layer and within sides of the protruding portion of the drift layer, a source layer within a portion of the well layer and extending into an undercut in the well layer and into the well layer along the sides of the protruding portion of the drift layer, a JFET layer within the protruding portion of the drift layer, an insulating layer over a portion of the source layer and over a portion of the well layer on the sides of the protruding portion of the drift layer, and a gate electrode over a portion of the insulating layer. The substrate may comprise a first concentration of a first type dopant. The drift layer may comprise a second concentration of the first type dopant, the first concentration may be greater than the second concentration. The well layer may comprise a third concentration of a second type dopant. The source layer may comprise a fourth concentration of the first type dopant. The JFET layer may comprise a fifth concentration of the first type dopant. The insulating layer may comprise polysilicon, oxide or a mixture of polysilicon and oxide. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 is a cross sectional view of a transistor according to one or more example embodiments;

FIG. 2A is cross sectional view of some of the steps in a method of manufacturing a transistor according to one or more example embodiments;

FIG. 2B is cross sectional view of some of the steps in a method of manufacturing a transistor according to one or more example embodiments;

FIG. 2C is cross sectional view some of the steps in a method of manufacturing a transistor according to one or more example embodiments;

FIG. 2D is cross sectional view some of the steps in a method of manufacturing a transistor according to one or more example embodiments;

FIG. 2E is cross sectional view some of the steps in a method of manufacturing a transistor according to one or more example embodiments; and

FIG. 2F a cross sectional view of some of the steps in a method of manufacturing a transistor according to one or more example embodiments.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

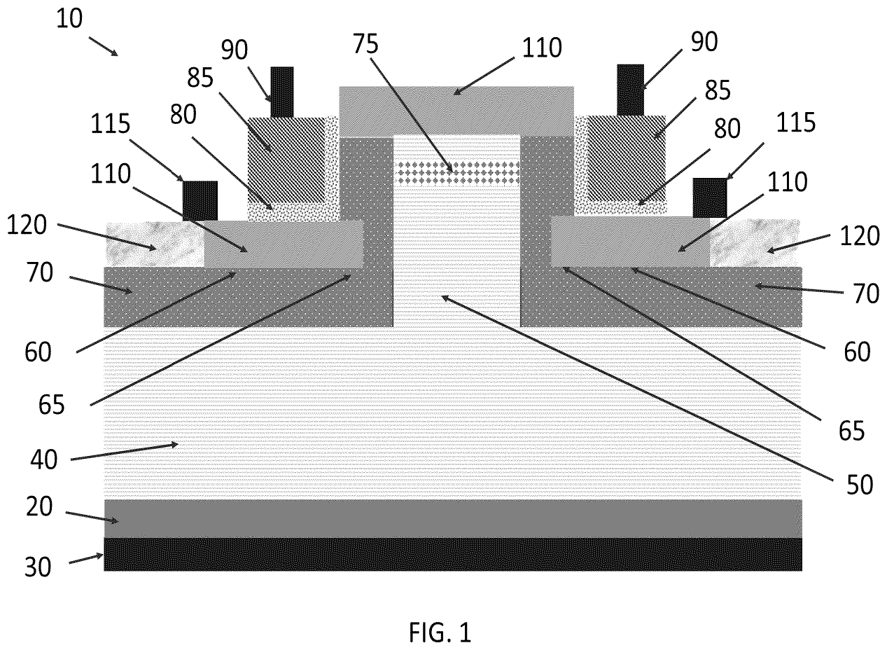

FIG. 1 is a cross sectional view of a transistor according to one or more example embodiments. As shown in FIG. 1, the transistor 10 may have a substrate 20 that may have a first concentration of a first dopant type. The substrate 20 may comprise bulk gallium nitride, diamond, silicon carbide, aluminum nitride, or silicon. The substrate 20 may be doped so as to have a resistivity of less than 25 milliohm-cm. A drain contact 30 may be formed on a first side of the substrate 20. The drain contact 30 may be made from a metal, polysilicon, or other suitable material. In FIG. 1, the example transistor 10 may include a drift layer 40 that may have a second concentration of the first type dopant and may be formed on a second side of the substrate 20, the second side opposite the first side. The first concentration of first type dopant in the substrate 20 is greater than the second concentration of first type dopant in the drift layer 40. The drift layer 40 may comprise bulk gallium nitride, diamond, silicon carbide, aluminum nitride, or silicon. The drift layer may have a protruding portion 50. In FIG. 1, the example transistor 10 may include a well layer 70 formed within the drift layer 40 and within sides of the protruding portion 50 of the drift layer 40. The well layer 70 may have a third concentration of a second type dopant. In FIG. 1, the example transistor 10 may include a source layer 110 within a portion of a recessed portion 60 of the well layer 70, extending into an undercut 65 within the well layer 70 and into the well layer along the sides of the protruding portion 50 of the drift layer 40. The source layer 110 may comprise a fourth concentration of the first type dopant. The fourth concentration of first type dopant in the source layer 110 may be greater than the second concentration of the first type dopant in the drift layer 40. In FIG. 1, the example transistor 10 may include a body layer 120 (this may be a body connection, a body extension or even a well connection) formed over a portion of the recessed portion 60 of the well layer 70. A portion of the source layer 110 may be adjacent to the body layer 120. In FIG. 1, the example transistor 10 may include a source contact 115 over the source layer 110 and the body layer 120. In FIG. 1, the example transistor 10 may include a JFET layer 75 within the protruding portion 50 of the drift layer 40. The JFET layer 75 may comprise a fifth concentration of the first type dopant. In FIG. 1, the example transistor 10 may include an insulating layer 80 over a portion of the source layer 110 and over a portion of the well layer 70 on the sides of the protruding portion 50 of the drift layer 40. The insulating layer 80 may comprise polysilicon, oxide or a mixture of polysilicon and oxide or any other insulating material. In FIG. 1, the example transistor 10 may include a gate electrode 90 connected to a poly layer 85 over a portion of the insulating layer 80. In operation, the transistor 10 of the present invention may allow for the flow of charged particles from the source layer 110 through the protruding portion 50 of the drift layer 40 to the drain contact 30.

In the example transistor 10 of FIG. 1, the first type dopant may be an n-type dopant with the second type dopant being a p-type dopant. Alternatively, the first type dopant may be a p-type dopant with the second type dopant being an n-type dopant.

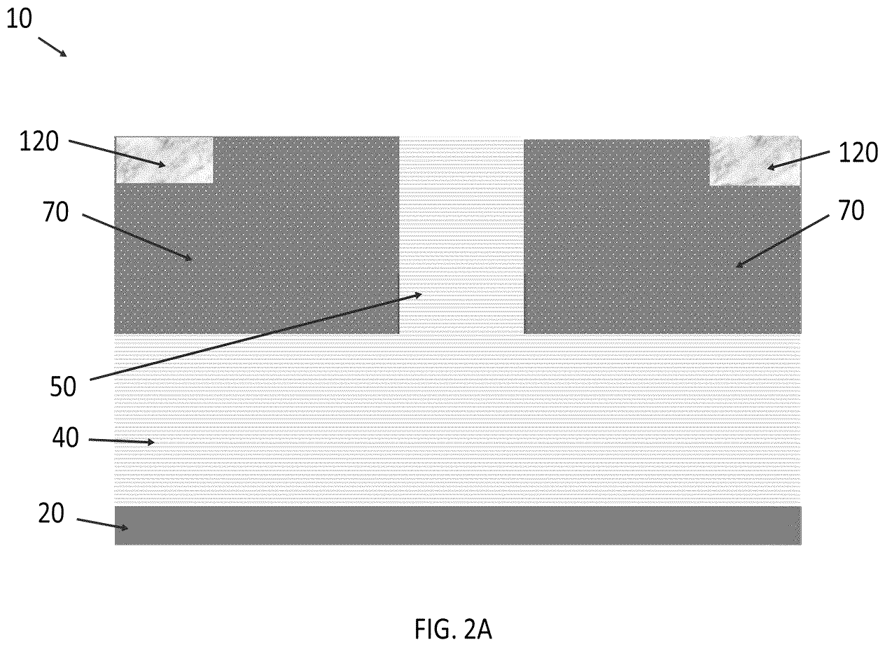

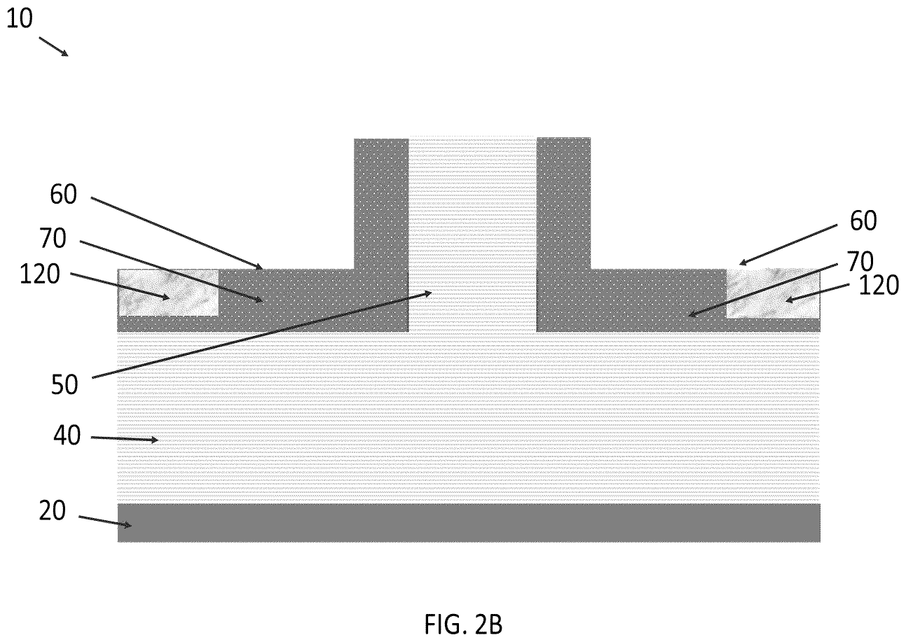

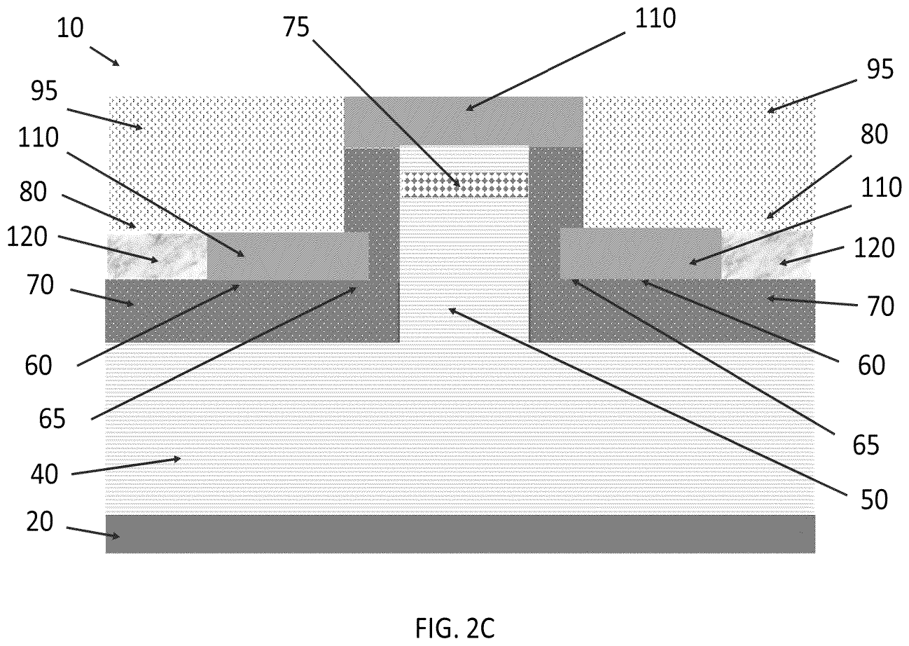

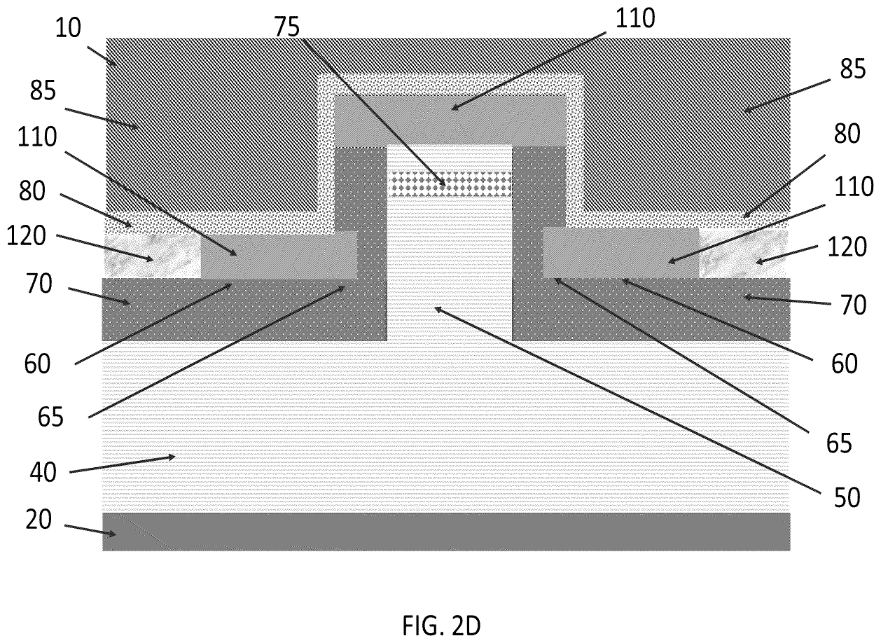

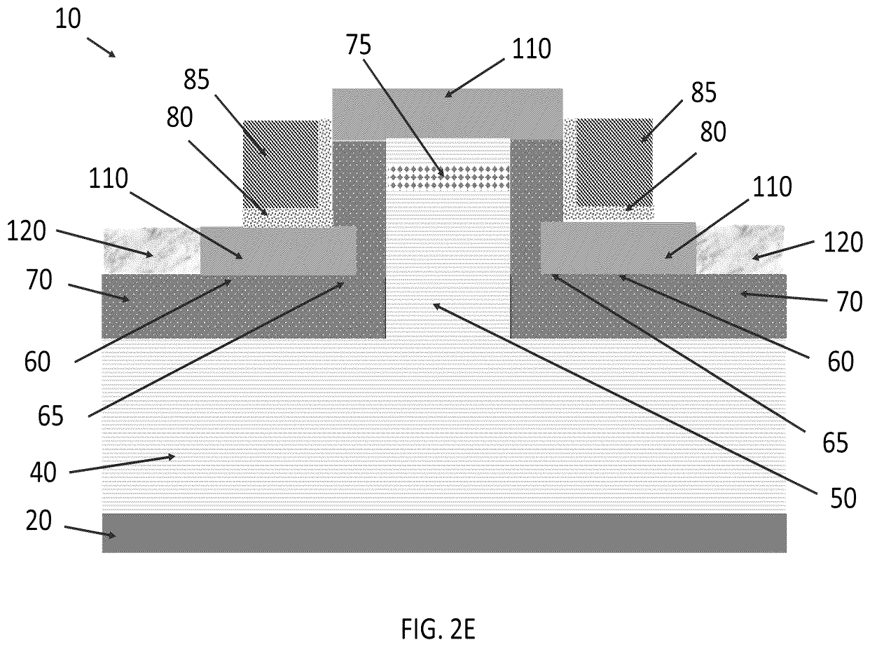

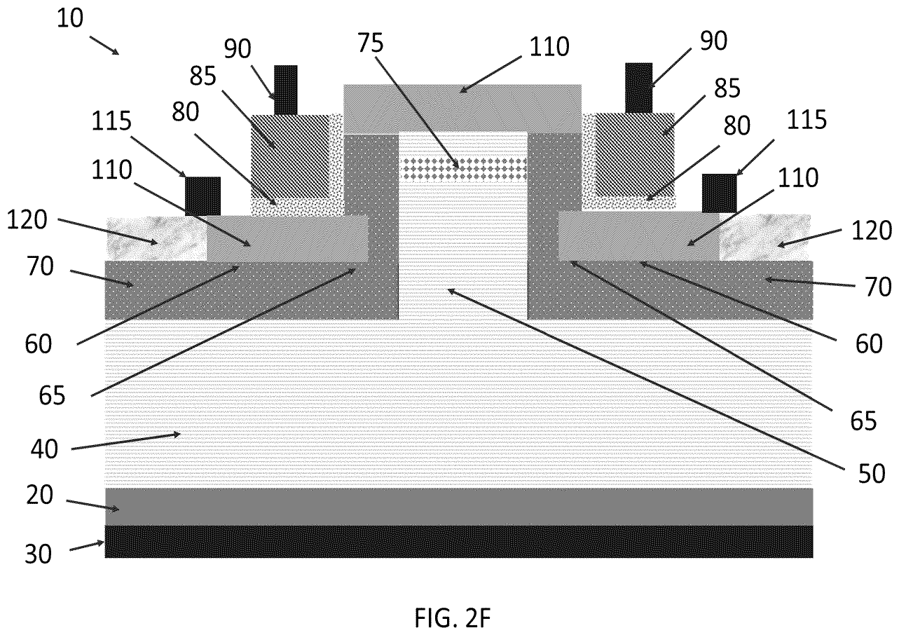

FIGS. 2A-2F show a method of manufacturing a transistor according to one or more example embodiments. Although the example method shown in FIGS. 2A-2F include steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A is a cross sectional view of some of the steps in a method of manufacturing a transistor 10 according to one or more example embodiments. In FIG. 2A, the example method may include providing a substrate 20 that may have a first concentration of a first type dopant. The first concentration of first type dopant in the substrate 20 is greater than the second concentration of first type dopant in the drift layer 40. The substrate 20 may comprise bulk gallium nitride, diamond, silicon carbide, sapphire, aluminum nitride, or silicon. The substrate 20 may be doped so as to have a resistivity of less than 25 milliohm-cm. In FIG. 2A, the example method may include forming a drift layer 40 on the substrate 20. The drift layer 40 that may have a second concentration of the first type dopant. The drift layer 40 may comprise bulk gallium nitride, diamond, silicon carbide, aluminum nitride, or silicon. In FIG. 2A, the example method may include implanting a well layer 70 into the drift layer 40 and sides of the protruding portion 50 of the drift layer 40. The well layer 70 may have a third concentration of a second type dopant. In FIG. 2A, the example method may include implanting a body layer 120 (this may be a body connection, a body extension or even a well connection) into a portion of the well layer 70.

FIG. 2B is a cross sectional view of some of the steps in a method of manufacturing a transistor 10 according to one or more example embodiments. In FIG. 2B, the example method may include forming a recessed portion 60 into the well layer 70 and body layer 120

FIG. 2C is a cross sectional view of some of the steps in a method of manufacturing a transistor 10 according to one or more example embodiments. In FIG. 2C, the example method may include implanting a source layer 110 within into a portion of the recessed portion 60 of the well layer 70 and extending into an undercut 65 in the well layer 70 and into the well layer 70 along the sides of the protruding portion 50 of the drift layer 40. The source layer 110 may comprise a fourth concentration of the first type dopant. The fourth concentration of first type dopant in the source layer 110 may be greater than the second concentration of the first type dopant in the drift layer 40. A portion of the source layer 110 may be adjacent to the body layer 120. In FIG. 2C, the example method may include a spacer 95 over the source layer 110 and the body layer 120. In FIG. 2C, the example method may include implanting a JFET layer 75 into the protruding portion of the drift layer. The JFET layer 75 may comprise a fifth concentration of the first type dopant.

FIG. 2D is a cross sectional view of some of the steps in a method of manufacturing a transistor according to one or more example embodiments. In FIG. 2D, the example method may include removing the spacer 95 of FIG. 2C. In FIG. 2D, the example method may include forming an insulating layer 80 over the source layer 110, over the body layer 120 and over the well layer 70 over the walls of the protruding portion 50 of the drift layer 40. The insulating layer may be polysilicon, oxide or a mixture of polysilicon and oxide or any other insulating material. In FIG. 2D, the example method may include forming poly layer 85 over the insulating layer.

FIG. 2E is a cross sectional view of some of the steps in a method of manufacturing a transistor according to one or more example embodiments. In FIG. 2E, the example method may include patterning the insulating layer 80 such that the insulating layer 80 may be over a portion of the source layer 110 and over a portion of the well layer 70 on the sides of the protruding portion 50 of the drift layer 40. The poly layer 85 may be patterned such that the poly layer 85 may be over a portion of the insulating layer 80 over a portion of source layer 110.

FIG. 2F is a cross sectional view of some of the steps in a method of manufacturing a transistor 10 according to one or more example embodiments. In FIG. 2F, the example method may include forming a gate electrode 90 over a portion of the poly layer 85. The gate electrode 90 may be made from a metal, polysilicon, or other suitable material. In FIG. 2F, the example method may include forming a source contact 115 operatively connected to the source layer 110 and the body layer 120. The source contact 115 may be made from a metal, polysilicon, or other suitable material. In FIG. 2F, the example method may include forming a drain contact 30 on an opposite side of the substrate 20 to the drift layer 40. In operation, the transistor 10 of the present invention may allow for the flow of charged particles from the source layer 110 through the protruding portion 50 of the drift layer 40 to the drain contact 30.

In the example transistor 10 of FIGS. 2A-2F, the first type dopant may be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method of manufacturing a transistor, the method comprising:
providing a substrate;
forming a drift layer on the substrate having a protruding portion;
implanting a well layer into the drift layer and into sides of the protruding portion of the drift layer;
forming a recess portion into the well layer;
implanting a source layer into a portion of the recessed portion of the well layer and extending into an undercut in the well layer and into well layer along the sides of the protruding portion of the drift layer;
implanting a JFET layer into the protruding portion in the drift layer;
forming an insulating layer over a portion of the source layer and over a portion of the well layer on the sides of the protruding portion of the drift layer; and
forming a gate electrode over the insulating layer.

2. The method of claim 1, wherein the substrate comprises a first concentration of a first type dopant.

3. The method of claim 2, wherein the drift layer comprises a second concentration of the first type dopant, the first concentration is greater than the second concentration.

4. The method of claim 3, wherein the well layer comprises a third concentration of a second type dopant.

5. The method of claim 4, wherein the source layer comprises a fourth concentration of the first type dopant.

6. The method of claim 5, wherein the JFET layer comprises a fifth concentration of the first type dopant.

7. The method of claim 6, wherein the insulating layer comprises polysilicon, oxide or a mixture of polysilicon and oxide.

8. The method of claim 7, wherein the first type dopant comprises an n-type dopant and the second type dopant comprises a p-type dopant.

9. The method of claim 7, wherein the first type dopant comprises a p-type dopant and the second type dopant comprises an n-type dopant.

10. A transistor comprising:
a substrate;
a drift layer on the substrate, the drift layer having a protruding portion;
a well layer within the drift layer and within sides of the protruding portion of the drift layer;
a source layer within a portion of the well layer and extending into an undercut in the well layer and into the well layer along the sides of the protruding portion of the drift layer;
a JFET layer within the protruding portion of the drift layer;
an insulating layer over a portion of the source layer and over a portion of the well layer on the sides of the protruding portion of the drift layer; and
a gate electrode over a portion of the insulating layer.

11. The transistor of claim 10, wherein the substrate comprises a first concentration of a first type dopant.

12. The transistor of claim 11, wherein the drift layer comprises a second concentration of the first type dopant, the first concentration is greater than the second concentration.

13. The transistor of claim 12, wherein the well layer comprises a third concentration of a second type dopant.

14. The transistor of claim 13, wherein the source layer comprises a fourth concentration of the first type dopant.

15. The transistor of claim 14, wherein the JFET layer comprises a fifth concentration of the first type dopant.

16. The transistor of claim 15, wherein the insulating layer comprises polysilicon, oxide or a mixture of polysilicon and oxide.

17. The transistor of claim 16, wherein the first type dopant comprises an n-type dopant and the second type dopant comprises a p-type dopant.

18. The transistor of claim 16, wherein the first type dopant comprises a p-type dopant and the second type dopant comprises an n-type dopant.
